(19) United States
(12) Patent Application Publication
(10) Pub. No.: US 2017/0227610 A1
(43) Pub. Date: Aug. 10, 2017

(54) MANAGEMENT OF THE RECHARGING OF THE BATTERY OF AN ELECTRIC VEHICLE

(71) Applicant: COMMISSARIAT A L'ENERGIE ATOMIQUE ET AUX ENERGIES AL ALTERNATIVES, PARIS (FR)

(72) Inventors: Boujemaa AIT EL FQUIH, LIVRY-GARGAN (FR); Cédric GOUY-PAILLER, VERSAILLES (FR); Sylvain GUILLEMIN, ALLEVARD (FR)

(21) Appl. No.: 15/503,002

(22) PCT Filed: Sep. 4, 2015
(86) PCT No.: PCT/EP2015/070197

§ 371 Date: Feb. 9, 2017

(30) Foreign Application Priority Data
Sep. 12, 2014 (FR) 1458563

(51) Int. Cl. G01R 31/36; H02J 7/00

(52) U.S. Cl. CPC G01R 31/3651; G01R 31/3627; G01R 31/3682; H02J 7/0029; H02J 7/0047

(57) ABSTRACT

A method implemented by computer for managing the recharging of a battery of an electric vehicle, comprises the steps of carrying out a recharging cycle of the battery of the electric vehicle; measuring the total energy stored by the battery; calculating the variance associated with the total energy; and determining a coefficient associated with the variance. In one development, the step of determining the coefficient associated with the variance is recursive. Various developments are described, which comprise the use of predefined and/or configurable thresholds, the emission of alarms, the use of white noise distributed according to a heavy-tailed law (e.g. Student) and the use of a Kalman filter. System and software aspects are described.

### FIELD OF THE INVENTION

The invention relates in general to the field of signal processing and in particular to the management of the recharging of the battery of an electric or hybrid vehicle.

### PRIOR ART

When recharging an electric vehicle (VE), certain so-called input parameters may influence the quantity of total electrical energy stored in the battery of this vehicle.

Published experimental studies have shown that the most influential input parameters are on the one hand the initial reserve which represents the energy remaining in the battery of the vehicle at the instant the recharging starts, and on the other hand, but to a lesser extent, the ambient temperature at the same instant.

It has been noted that by varying the input parameters, the total energy stored evolves on average linearly and with a constant variance. Stated otherwise, the relationship between the total energy stored and the input parameters can adequately be represented by a linear model with white additive noise, i.e. Gaussian with a constant variance.

However, in atypical situations such as for example in the presence of anomalies at the level of the charging of said battery, the total energy stored may attain extreme values, that do not fit with the Gaussian assumption of the noise of the model.

Concerning this technical problem consisting in conducting robust detection of anomalies of recharging of an electric car on the basis of the signals arising from the recharging terminals, the patent literature (in the field of transport) comprises patent application US2011/0254505, the objective of which is to protect (e.g. monitor) a battery recharging system from possible acts of vandalism or theft during the charging process (for example by the removal of the cable transferring the energy from the terminal to the vehicle by a third party so as to connect it up to another vehicle). This approach deals only with the “static” case (i.e. during one and the same recharging cycle) and does not afford any solution to the problem of detecting atypical recharges as the recharges proceed (i.e. “dynamic” case).

Possible disclosures in technical fields foreign to the field of transport are not very likely and would be difficult to utilize in principle, on account of the very specific features of batteries destined for electric vehicles.

A need exists for systems and methods for analyzing the electrical measurements performed during the recharging of the battery of an electric vehicle (VE) or hybrid vehicle (VH), with a view to discerning possible singular behaviors.

### SUMMARY OF THE INVENTION

There is disclosed a method for detecting anomalies of recharges of electric vehicles on the basis of the signals arising from the recharging terminals. In particular, according to one aspect of the invention, the recharging of an electric vehicle is monitored and/or analyzed (e.g. the total energy stored during the recharging of an electric vehicle, detection of aberrant recharges).

According to one aspect of the invention, there is undertaken the recursive estimation of the weights associated with the variances of the measurements together with coefficients of the model. The recursive characteristic means that in practice the estimation uses just the measurement associated with the current recharging and the estimation associated with the previous recharging. The fact of using only the measurement associated with the current recharging is advantageous (in regard to efficiency and speed of the calculations).

Optionally, the method can utilize the measurements of the energies in the course of the entire history of the recharges (therefore the past and present measurements).

Advantageously, the method described is robust to the presence of possible aberrant values among the measurements of the total energy stored.

Advantageously, the detection of aberrant values is automated. The detection criterion can be based on the comparison of the estimated weights (therefore with the help of already available numerical values) with respect to a predefined threshold (fixed beforehand by the user). Certain embodiments do not require any manual settings.

Advantageously, in certain embodiments, the method can allow the “instantaneous” (i.e. real-time or quasi-real-time), or at the very least fast (i.e. between detection and signaling of an anomaly), detection of one or more aberrant values. Detection of this type advantageously allows specialists to diagnose in good time the state of the battery, and to discern the type of anomaly concerned. For each recharging cycle, if the total energy stored on completion of this cycle corresponds to an aberrant value, an item of information can be notified or sent to the user (e.g. alarm) and/or to the supplier of the battery (or to another authorized third party, for example)

Advantageously, the solution disclosed can be iterated (e.g. recursively), affording efficiency and speed of the associated calculations.

Advantageously, the solution can detect the anomalies of the recharging mechanism and not anomalies to do with the battery itself.

### DESCRIPTION OF THE FIGURES

Various aspects and advantages of the invention will become apparent in support of the description of a preferred but nonlimiting mode of implementation of the invention, with reference to the figures hereinbelow:

FIG. 1 is an overall diagram of the method;

FIG. 2 represents an exemplary dynamic model;

FIG. 3 illustrates an exemplary mechanism for estimating the coefficients xₙ and the weight wₙ which are associated with a recharge n>1 (in the case #ID=1).

FIG. 4 illustrates an exemplary estimation of F, Q and σ² on completion of a recharge n>1 (in the case #ID=1).

### DETAILED DESCRIPTION OF THE INVENTION

There is disclosed a method implemented by computer for managing the recharging of a battery of an electric vehicle, comprising the steps consisting in carrying out a recharging cycle of the battery of the electric vehicle; measuring the total energy stored by the battery; calculating the variance associated with said total energy; and determining a coefficient associated with said variance.

The invention can apply to various types of battery. For example, car batteries, but also batteries of electric bikes, of electric kick scooters or else of other types of vehicles. The invention also finds application in respect of hybrid vehicles (combining motor and therefore electric battery and combustion engine).

The invention is aimed at managing the recharging of an electric battery, in the broad sense. In particular, the invention is aimed at detecting a recharging anomaly.

The general framework of the invention is that in which substantially complete recharging cycles are undertaken. For example, the standard scenario is that where recharging is performed in the parking lot of the workplace during the day, the vehicle being retrieved charged at the end of the day. The case of incomplete or intermittent recharges poses particular technical problems and, apart from exceptions, this type of recharging does not form part of the invention. In particular and for example, the scenario of incomplete recharges may be encountered in the recharging of mobile electronic devices (e.g. smartphones). With electric vehicles, recharges are performed at low cost and there is therefore no justification in investigating hereafter the situation of short and/or incomplete recharges.

A recharging cycle corresponds to a recharge according to a duration and modalities that are predetermined or nominal and generally provided by the maker or supplier of the battery.

The general context of the invention is generally tripartite. Provided by a supplier or maker or assembler, generally just one, the battery is operated by one or more recharging terminal operators (that may be competing) in such a way as to effectively recharge the battery for the customer or driver, also the operator of the recharge properly speaking. Other entities may be involved, for varied purposes (certification, quality control, electricity supplier, etc). For example, a service provider may also be involved in order to optimize the lifetime of the battery (e.g. by independently measuring the state of the battery, by analyzing the type of driving, by undertaking correlations to provide the drivers with recommendations etc). Telecommunications operators or publishers of software packages (“apps”) might also manage the information associated with the batteries.

One of the aspects of the invention consists in observing (independently) the state of the batteries, i.e. without necessarily taking account of the supplier's declarations as regards the characteristics (for example nominal) of these batteries. This observation is done by direct measurement or calculation.

According to one aspect of the invention, the history of the battery is advantageously utilized, in such a way as to more precisely tune the model (with predictive charge capacity). However, it is not essential to take the history into account.

The total energy stored can be determined by various procedures. In one embodiment, the recharging terminal comprises one or more method steps and/or system means for detecting that charging is “complete” (detection is therefore integrated so as to judge that the battery is “full” or “recharged” or “complete”). According to this embodiment, there may not necessarily be any “communication” (in the sense of data) between the battery to be recharged and the recharging terminal. It is possible to detect or determine this state of “complete” recharging according to various procedures (which can notably depend on the battery technology). In one embodiment of the invention, the recharging terminal can therefore stop the charging automatically when the terminal detects that charging is complete. In one embodiment, the recharging terminal can therefore provide all the data for example relating to the end of charging, or else to total energy quantity that has been transferred (for example by integration, i.e. by integrating the power provided over time).

The losses in charge can be considered to be negligible (in theory and in practice). The application of the principle of conservation of energy leads in particular to the equality of the energies delivered and received (battery and terminal operate as a “pair”, i.e. “mirror”-like).

The measurement of the total energy stored by the battery is generally performed after the end of the recharging cycle of said battery (that is to say actually as soon as charging has terminated, or else “after” i.e. in a manner offset in time). Nonetheless, the temporal criterion associated with the accomplishment of a recharge must be considered in a nonlimiting manner. Indeed, embodiments of the invention exist according to which charging may not have terminated entirely (i.e. according to thresholds, optionally configurable for example according to the type of battery and/or the recharging situation—express, slow, etc—and/or the vehicle user's desire and/or statistical confidence thresholds associated with the recharging model). The term “cycle” implies per se implicitly that recharging has terminated or is considered to have terminated.

Stated otherwise, the determination of the total value stored can be done according to various temporal modalities. It can be done as soon as the recharging cycle has finished (according to the terminal and/or according to the battery). More precisely, it can be performed at a moment determined either by the recharging terminal or by the battery itself, or else by a logic module managing the terminal-battery pairing and managing the possible inconsistencies between the two systems. It can be done “once” the value of the total energy stored has been determined or “as soon as” the value is determined or “after” this determination, optionally within a certain limit time lag after the end of the cycle.

The numerical value of the mathematical variance associated with this total value stored is thereafter determined in its turn. On the basis of the measurement of the total energy stored, a value, generally numerical, for example a mathematical variance associated with this total energy, is determined (or calculated or estimated or deduced). The term association implies that the relation may sometimes be indirect (for example certain assumptions of white noise and distribution of this noise according to a Student's law or one of the same mathematical class can allow this determination).

The variance indicates the degree of likelihood of the measurement performed. This likelihood is taken into account in establishing the predictive model and for the subsequent filtering of the aberrant values.

A weight (i.e. a weighting), also called a “coefficient”, is thereafter assigned to this variance thus determined. This coefficient makes it possible to “tune” the model.

In one development, the step of determining the coefficient associated with the variance is recursive.

The notion of recursivity implies the presence of an initialization and of a previous state.

In one embodiment, said coefficient is determined in a recursive manner. The predictive charge model is “tuned” by means of the past values of charges. The higher the number of past values, the better the reliability of the model. At each iteration (i.e. recharge) the model becomes “better”, that is to say incorporates the entire set of past recharging operations.

The model requires two values: the measurement which is carried out at the end or after the recharging cycle and (at least) a previous value. This previous value can have various sources (corresponding to several different embodiments).

In one embodiment, the previous value is accessible directly from the battery itself (which therefore stores the various recharging values), or indirectly (distributed or remote storage). The previous value can be a measured value (i.e. in reality) or else a reference value, for example estimated (e.g. from a chart) or calculated or accessed from a network. In particular, this value can be estimated by knowing the states associated with a fleet of similar vehicles. It is indeed possible, according to one embodiment, to carry out calculations without having access to the history of the battery (for example if the previous charge value is not accessible or is manifestly erroneous, etc). For example, one or more of these values of total energy stored can be determined in a statistical manner (e.g. according to the battery model, the general state of the battery pool), according to aggregated data, optionally comprising third-party data, etc. The two embodiments can also be combined: available statistical data can confirm or indeed modulate the direct measurements and/or the inclusion of the history. In addition, probabilistic procedures can also be used (as a supplement or in the absence of statistical data and/or of specific history).

The recharging cycles can be repeated, and this may lead to a progressive improvement in the quality of the model. In practice, the recursive characteristic corresponds to a determination of the weight or coefficient assigned to the variance which uses the measurement associated with the current recharging cycle and a measurement associated with the previous recharge.

In one development, the method furthermore comprises a step consisting in comparing the coefficient as determined with one or more thresholds.

Various ranges of thresholds can indeed be defined. The thresholds are generally predefined. In certain embodiments, thresholds can be defined dynamically (for example as a function of economic and/or technical considerations, for example related to the chemistry of the battery).

In one development, the predefined threshold is configurable.

The economic environment of the invention is complex and is liable to entail a number of consequences (e.g. conflicts of interest, competition, secret or declarative or measured information) which may consequently imply possibly very different solutions of a technical character. For example, with operational hindsight, an operator may be obliged to revise the nominal charging values declared by the maker. The user or customer or driver (or a service provider working for said customer) may in certain embodiments choose the mode of recharging (for example “fast” or “slow” or according to various other modes exhibiting different compromises in regard to electrical or chemical risk or to speed or to quality or to power of charge), i.e. manage the battery in a more or less cautious manner. In the case where the battery is not the property of the driver, but for example rented, other parties are liable to be involved. The information associated with the battery may be in a prescribed format or on the contrary an unrestricted format, be accessible as plaintext or be encrypted (e.g. the discharge profile if it is analyzed may reveal driving styles or indeed excessive speeds). The information or data may be hosted in the “cloud” (“cloud computing”) or remain local (for example portable), or else result from a distribution of data between the “cloud” and portable data.

In one development, the method comprises a step consisting in emitting an alarm if the measurement of the total energy stored determined is greater than one or more thresholds.

If appropriate, an alarm signal can be sent informing the user or the customer or the driver or the operator of the recharging terminal of the presence of an anomaly. The alarm can be “real time” (insofar as it is necessary to wait until the end of the recharging cycle in progress in order to detect an anomaly).

In one development, the calculation of the variance is associated with white noise distributed according to a heavy-tailed distribution law.

Based on a white noise (anisotropic) assumption, a so-called “heavy-tailed” mathematical distribution is used to calculate the variance. Stated otherwise, the measurement of the total energy stored by the battery is marred by white noise distributed according to a Student's law.

In one development, the heavy-tailed distribution law is a Student's law.

In a particular case, a Student's law is used. This distribution lends itself advantageously to fast calculations. However, other distributions remain possible.

In one development, the step consisting in determining a coefficient associated with the variance of the measurement of the total energy stored by the battery comprises a step consisting in using a Kalman filter.

The method makes it possible to utilize, on the one hand, the measurements of the energies carried out in the course of the history of the recharges (which comprises the past measurements) and, on the other hand, the “present” or “current” or “ongoing” measurement or measurement “in progress”.

In particular, in one embodiment, the method can comprise a step consisting in determining a coefficient associated with the variance of the measurement of the total energy stored by the battery, said step comprising a step consisting in using the Kalman filter prediction step to detect a recharging anomaly, and the Kalman filter correction step to refine (i.e. to render the model more precise and therefore “better”) and update (i.e. to take account of slow evolutions of the battery which are not considered to be anomalies).

The Kalman filter makes it possible to filter (efficiently) the abnormal recharges by relying on two phases. Initially, the prediction step makes it possible to compare the present measurement with the prediction made by the model under the conditions of the present charging. From this comparison there results an anomaly according to the threshold defined above. Subsequently, the Kalman model correction phase updates the model so as to refine its precision and to take account of possible slow drifts of the parameters tracked, not considered to be abnormal (“conventional” life of the battery).

The corresponding algorithms and source codes are widely available, rendering actual implementation easier (for example Boujemaa Ait-El-Fquih, Cédric Gouy-Pailler: “Backward hidden Markov chain for outlier-robust filtering and fixed-interval smoothing” ICASSP 2013: 5504-5508).

In one development, said Kalman filter is applied to a plurality of past total energy measurements.

This aspect of the invention relates to the phase of “prediction” or tuning of the model. Access to the history of the measurements makes it possible to improve the reliability of prediction of the model by carrying out a precise estimation of the various parameters of the Kalman filter, involved in the evolution equations (e.g. given that the model can evolve from one recharge to the next) and observation equations (e.g. to quantify the noise present in the data).

In one development, the method furthermore comprises the inclusion of the measurement of the total energy associated with said recharging cycle in progress.

According to this development, the measurement of the total energy associated with the ongoing or present recharge or recharge in progress is taken into account so as to undertake the updating (“looping” of the “tuning”) of the prediction model. This may entail simply reading off on the terminal. In the details of the implementation, the step may (optionally) comprise a sub-step of Expectation-Maximization type.

In one development, the method furthermore comprises a step consisting in storing one or more measurement values of total energy stored and one or more coefficients associated with the variances of said measurement values.

The estimated coefficients can indeed be saved or stored so as to be reused during a future recharge. Actually, the data can be centralized (central server connected to the recharging terminals) or else distributed (for example in a memory associated with the battery of the vehicle and accessible to the recharging terminal). The data can be stored in part or entirely on a portable telephone and/or in a remote server and/or in the car's onboard computer and/or in the recharging terminal and/or in the battery itself or an associated apparatus, for example.

Numerous embodiments are possible (and may be combined).

According to one embodiment, the manufacturer of the recharging terminal can include the recharging service in their own commercial offer, ensuring the integrity of the data so that a user can have access in “cloud” mode (“cloud computing”) to its follow-up (for example to the associated model as well as to the various measurement data) and thus foster the customer's loyalty to a maker of terminals (or a consortium sharing the data with one another).

According to one embodiment, the manager of a cluster of recharging terminals can keep the associated data on their own system, so as to offer the tracking/diagnosis service to users when the latter recharge on their cluster (for example according to a proprietary model).

According to one embodiment, the user possessing a home recharging socket can manage the recharging service directly, in which case autonomous operation is possible with data that may for example remain stored in the recharging terminal and/or the computer of the user (the ability to share or not share said data remaining open to the user, for example in order to access additional functionalities or services or data processing, such as comparing between similar batteries of different users, etc).

In one development, the method furthermore comprises a step consisting in receiving an initial reserve value and an ambient temperature value.

The method can furthermore comprise a step consisting in receiving input parameters comprising an initial reserve value and an ambient temperature value.

In fact, the predicted energy depends mainly on the reserve a(n) and on the temperature t(n) such as described in equation 1 described hereinafter. However, these values are not essential, i.e. indispensable for carrying out the method according to the invention. For example, the temperature can be considered to be a constant, an average, be provided by a third party system (e.g. telephone, operator, etc). The reserve value can also be estimated or calculated or provided by a third party system or according to charts or databases, etc. On the contrary, the fact of having real values, with a satisfactory or reasonable degree of accuracy, makes it possible to advantageously refine the model.

The method according to the invention is aimed at detecting the aberrant values of the total electrical energy stored during the charging of an electric or hybrid vehicle (identified by a unique identification code).

Therefore, according to one aspect of the invention, a linear and robust dynamic model is implemented. In particular, the model associates a weight with the variance of each measurement of the total energy stored.

According to another aspect of the invention, recursive steps of estimating the weights associated with the variances of these measurements are implemented. Aberrant measurements can consequently, if appropriate, be detected in real time (by using said estimated weights).

Alerts can inform the user or the operator recharging the battery of the presence of an anomaly (and of its type).

Certain embodiments are described in greater detail hereinafter.

A dynamic model relates, for each recharging cycle, the total energy stored to the input parameters (known at the moment that recharging commences), namely the initial reserve and the ambient temperature.

For a recharge (n=1, 2, . . . ), the following notation is considered hereafter:

eₙ: the total energy stored;

aₙ: the initial reserve measured by the recharging system at the moment that recharging commences (the recharging system is assumed to be furnished with a device for acquiring the reserve);

tₙ: the ambient temperature at the moment that recharging commences.

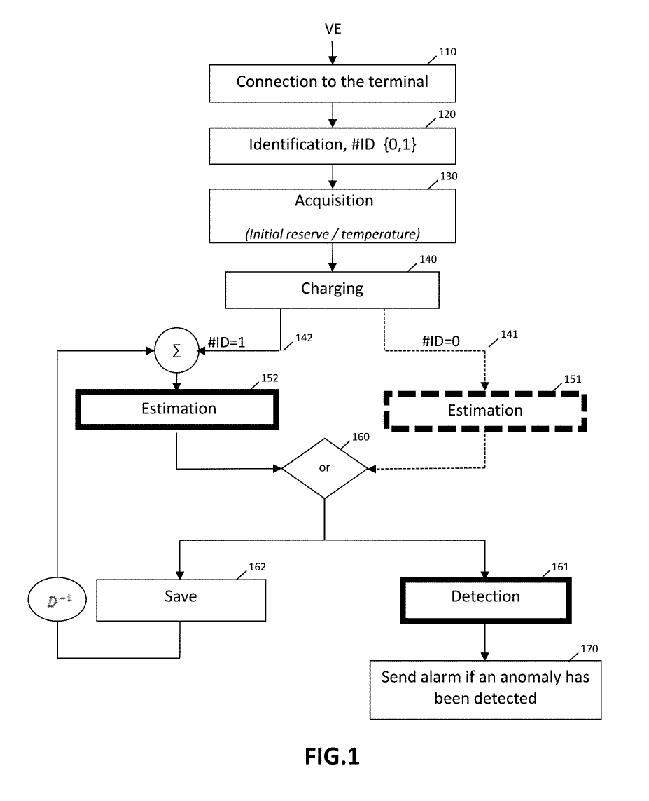

FIG. 1 illustrates examples of the various steps of the method.

In the connection step 110, the user connects the electric vehicle to the recharging terminal.

In the identification step 120, the identification of the VE by the recharging system is performed by virtue of an identification code unique to each VE. If the VE has been identified, that is to say if it has been recognized as having already been connected and recharged by this system, the latter assigns the value 1 to a binary variable #ID initially equal to 0. This step makes it possible, in the case where the VE has been identified, to access the historical data liable to be saved during the past recharges and to utilize them in the monitoring, making it possible to see if the present recharge corresponds to an anomaly.

In the acquisition step 130, the recharging system measures, by means of a device (for example integrated), the reserve remaining in the battery of the VE together with the ambient temperature.

In the charging step 140, after the acquisition of the initial reserve and the ambient temperature, the charging of the battery of the VE can then start. On completion of the recharge, the system measures the quantity of total electrical energy stored. The acquisition step 130 and charging step 140 do not depend (or not necessarily) on the result of the identification step 120: the value of the variable #ID on exiting step 120 does not come into steps 130 and 140. For this reason, the identification step 120 can also be done, either simultaneously with one of steps 130 and 140, or between them (after 130 and before 140), or after step 140.

The estimation step is illustrated in blocks 151 and 152. The principle of the estimation step is to ascertain the parameters of the model put in place (among other variables, as explained hereinafter). The data on the basis of which the estimation is made depend on the fact of whether or not the VE has been recognized in the identification step. Indeed, if the VE has not been recognized (#ID=0), then the case is that of the very first recharge (absence of history) in which the estimation is made by using the total energy stored subsequent to this recharge (block 150). On the other hand, when the VE has been recognized (#ID=1), the estimation also uses the history of the total energies stored and saved by the recharging system (block 152). These steps are described hereinafter.

In the detection step 160, the estimated weight is used in a detection criterion to show whether (or not) the value of the total energy stored is aberrant. The detection criterion is described in detail hereinafter.

In the alert step 170, an alarm signal is immediately sent by the system if the detection step has revealed that the total energy stored is an aberrant value. This will allow the user to diagnose in good time the battery liable in this case to suffer from an anomaly (caused for example by the aging of the battery).

In the saving step 162, which can be implemented simultaneously or after the step of detection and/or of alarm sending, the total energy stored in the battery together with the estimated coefficients of the model are saved by the recharging system so as to be used in the estimation step associated with future recharging if appropriate.

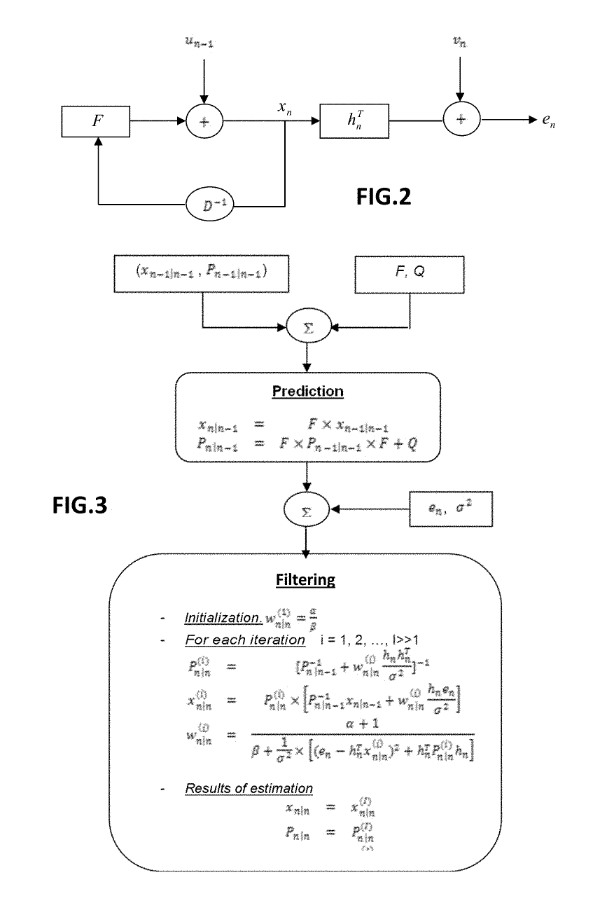

FIG. 2 shows diagrammatically the underlying dynamic model used by the method. The model chosen for the implementation of the method is a dynamic state model for which the measurements of the total energy stored are marred by white noise distributed according to a Student's law, which is a so-called “heavy-tailed” law.

The introduction of a heavy-tailed law at the level of the measurements is advantageous from a practical standpoint, in the sense that this law tolerates a larger probability of presence of the aberrant (or extreme) values at the level of the measurements in contradistinction to the Gaussian law which, for its part, considers that 99% of the measurements are normal and gives a chance of only 1% to the occurrence of extreme values.

In the model selected, each measurement of total energy stored can be associated with an artificially introduced variable modeling the weight of the variance associated with this same measurement.

Stated otherwise, in contradistinction to the conventional model with fixed-variance Gaussian noise, the model selected assigns a different weight to each of the variances of the measurements so as to render them variable (in such a way that the lowest weights are associated with the measurements having a tendency to be aberrant and/or extreme).

Moreover, optionally, recursive calculations based on the use of a Kalman filter make it possible to estimate, on completion of each recharging cycle, the weight associated with the variance of the measurement of the total energy stored (among other estimated variables).

The estimated weights are particularly advantageous during the detection step since, by using a threshold fixed by the user, the measurements are considered to be aberrant or not depending on whether the associated weights are less than or greater than the fixed threshold.

Hence, in contradistinction to the known detection procedures which are based for example on the confidence interval (for example), and which require on the one hand the Gaussian assumption regarding the error of reconstruction of the measurements, and on the other hand the possibility of calculating the bounds of the confidence interval, the presently disclosed detection step is based only on comparing the weights (i.e. already calculated) with respect to a predefined threshold, without any other additional calculation or assumption. Advantageously therefore, detection is done in an automatic manner and without any manual setting.

The mathematical model is described in detail hereinafter.

For readability, the input parameters and the digit 1 are concatenated in one and the same vector hₙ=[aₙ,tₙ,1]^{T} where “·^{T}” designates the transpose of a vector or a matrix.

The model is based on two equations:

$$\{ \begin{matrix}{x}_{n} = {Fx}_{n - 1} + {u}_{n} \\ {e}_{n} = {h}_{n}^{T} {x}_{n} + {v}_{n}\end{matrix} , \qquad ( equation 1 )$$

for which:

xₙ is a coefficient varying randomly in the course of the recharging cycles (in the course of n). Its dynamics are governed by said transition matrix F and a Gaussian random variable uₙ which is independent in the course of the recharges, centered and with covariance matrix Q. Moreover, on initialization, or equivalently during the 1^{st} recharge (n=1), a value of x₁ is assumed to be generated according to a Gaussian law with mean μ and covariance matrix Σ; and

vₙ is a random variable which is independent in the course of the recharges and models the noise of observations (or of measurements). This variable by assumption follows a centered Gaussian law conditionally upon an independent auxiliary random process wₙ following a Gamma law, with

$$p ( {v}_{n} \vert {w}_{n} ) = N ( 0 , \frac{{σ}^{2}}{{w}_{n}} ) , and p ( {w}_{n} ) = Γ ( α , β ) \qquad ( equation 2 )$$

The properties (equation 2) ensure that the noise vₙ associated with the observation (or the measurement of the energy) eₙ follows a Student's law which, let us note, is a heavy-tailed law, thus enabling the aberrant values of the energy to be better represented by the model. The parameters α and β of the Gamma law p(wₙ) are assumed to be known and fixed by the user.

The inventory of the variables to be estimated is now established and the estimation mechanism is described hereinafter.

The following notation is used hereafter for any non-zero integer n and m.

x_{n|m}: estimation in the sense of the minimization of the mean square error of xₙ based on the total energy stored subsequent to the m^{th} recharge eₘ together with its history {e₁, e₂, . . . , eₘ₋₁} if the latter exists (when #ID=1).

P_{n|m}: the covariance matrix associated with the estimation x_{n|m}.

w_{n|m}: estimation of the weight wₙ knowing eₘ and its history {e₁, e₂, . . . , eₘ₋₁} if the latter exists.

For each recharge n, the estimation of the coefficients and of the weight is made by a Kalman filter based approximate calculation algorithm. However, this calculation requires the knowledge of the model, that is to say of the initial parameters μ and Σ, the transition parameters F and Q and the variance, which are unknown a priori, thus making their estimation necessary in addition to that of xₙ and wₙ. Accordingly, we use an algorithm of EM (Expectation-Maximization) type. These two mechanisms, that is to say that of estimating the coefficients xₙ and weights wₙ, and that of estimating the parameters of the model μ, Σ, F, Q and are described hereinafter.

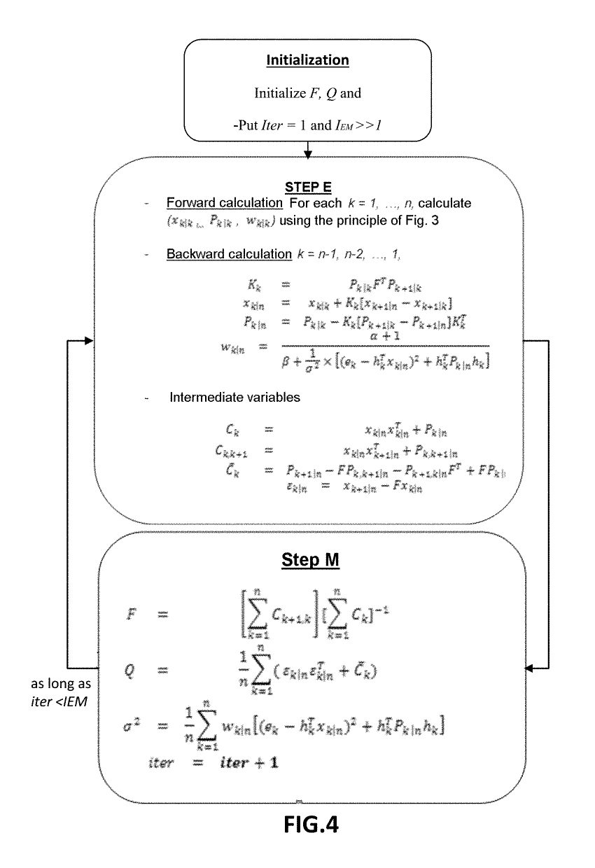

FIG. 3 shows diagrammatically examples of steps of estimating the coefficients xₙ and weights wₙ. FIG. 3 presents a situation in which a history of the total energy stored is available (#ID=1). The calculation is based on the use of a Kalman filter and comprises notably two steps: a so-called prediction step for which the estimation utilizes the past measurements of the total energy stored, and a filtering step which for its part also integrates the energy associated with the current recharge.

For the prediction step, use is made of the transition parameters of the model F and Q so as to calculate the prediction estimation x_{n|n-1} and its associated covariance matrix P_{n|n-1} on the basis of the filtering matrix associated with the previous recharge x_{n-1|n-1} and its associated covariance matrix P_{n-1|n-1}.

For the filtering step, the calculation is done iteratively. The step is a correction step since the prediction estimation (x_{n|n-1}, P_{n|n-1}) is corrected by integrating the current measurement eₙ with the past measurements, thereby leading to the filtering estimation (x_{n|n}, P_{n|n}). An estimation w_{n|n} of the weight wₙ is also provided.

In the course of the initial recharge (#ID=0), the prediction step disappears and only the filtering equations remain valid making it possible to calculate an estimation of x₁ and of w₁ on the basis of e₁; in these equations the prediction parameters x_{n|n-1}, P_{n|n-1} are replaced with μ, Σ respectively.

FIG. 4 illustrates the step of estimating the parameters μ, Σ, F, Q and σ² in the case where a history of recharges is available (#ID=1).

These parameters are estimated with the aid of an EM-based algorithm making it possible to maximize said likelihood of the complete data p(x₁, w₁, B₁, . . . xₙ, wₙ, eₙ) (or its logarithm). From the practical standpoint, the EM algorithm used is iterative and each of the iterations consists of two steps: a calculation step (or Expectation step) and a maximization step. These steps are described in the case where a history of recharges is available (#ID=1). In the course of the 1^{st} recharge (absence of history #ID=0), the transition mechanism is not yet triggered. Therefore, the transition parameters F, Q disappear and only μ, Σ and σ² are estimated. For this purpose, step E is replaced with the filtering step with n=1, and step M is done with k=n=1.

The detection step 161 is described hereinafter.

For a recharge n, our criterion is based on the estimated weight w_{n|n}. Indeed, by utilizing the fact

$${ξ}_{n} = \frac{β}{α + 1} {w}_{n \vert n}$$

lies between 0 and 1 it is possible to put:

ξₙ<threshold [symbol] the energy eₙ is an aberrant value.

The value threshold is chosen between 0 and 1 (generally very small). This criterion is based on the fact that the recharges having a low weight w_{n|n} (therefore a significant measurement variance

$$\frac{{σ}^{2}}{{w}_{n \vert n}} )$$

are considered to be atypical.

There is disclosed a system for detecting an anomaly of recharging of a battery of an electric vehicle, the system comprising means for implementing one or more steps of the method.

There is disclosed a computer program product, said computer program comprising code instructions making it possible to perform one or more steps of the method, when said program is executed on a computer.

There is disclosed a data medium comprising code instructions making it possible to perform one or more steps of the method, when said code is executed on a computer.

The present invention may be implemented on the basis of hardware elements and/or software elements. It may be available in the guise of computer program product on a computer readable medium. The medium may be electronic, magnetic, optical, electromagnetic or be a diffusion medium of infrared type.

1. A method implemented by computer for managing the recharging of a battery of an electric vehicle, comprising the steps consisting in:
carrying out a recharging cycle of the battery of the electric vehicle;
measuring the total energy stored by the battery;
calculating the variance associated with said total energy; and
determining a coefficient associated with said variance.

2. The method as claimed in claim 1, the step of determining the coefficient associated with the variance being recursive.

3. The method as claimed in claim 2, further comprising a step consisting in comparing the coefficient as determined with one or more thresholds.

4. The method as claimed in claim 3, the predefined threshold being configurable.

5. The method as claimed in claim 3, further comprising a step consisting in emitting an alarm if the measurement of the total energy stored determined is greater than one or more thresholds.

6. The method as claimed in claim 1, the calculation of the variance being associated with white noise distributed according to a heavy-tailed distribution law.

7. The method as claimed in claim 6, the heavy-tailed distribution law being a Student's law.

8. The method as claimed in claim 1, the step consisting in determining a coefficient associated with the variance of the measurement of the total energy stored by the battery comprising a step consisting in using a Kalman filter.

9. The method as claimed in claim 8, said Kalman filter being applied to a plurality of past total energy measurements.

10. The method as claimed in claim 9, further comprising the inclusion of the measurement of the total energy associated with said recharging cycle in progress.

11. The method as claimed in claim 1, further comprising a step consisting in storing one or more measurement values of total energy stored and one or more coefficients associated with the variances of said measurement values.

12. The method as claimed in claim 1, further comprising a step consisting in receiving an initial reserve value and an ambient temperature value.

13. A system for detecting an anomaly of recharging of a battery of an electric vehicle, the system comprising means for implementing the steps of the method as claimed in claim 1.

14. A computer program product, said computer program comprising code instructions to perform the steps of the method as claimed in claim 1, when said program is executed on a computer.

15. A data medium comprising code instructions to perform the steps of the method as claimed in claim 1, when said program is executed on a computer.
